(19) United States
(12) Patent Application Publication
(10) Pub. No.: US 2026/0327797 A1
(43) Pub. Date: Oct. 22, 2026

(54) METHOD OF PROCESSING SUBSTRATE, METHOD OF MANUFACTURING SEMICONDUCTOR DEVICE, RECORDING MEDIUM, AND SUBSTRATE PROCESSING APPARATUS

(71) Applicant: Kokusai Electric Corporation, Tokyo (JP)

(72) Inventors: Tao LIU, Toyama-shi (JP); Kazuyuki OKUDA, Toyama-shi (JP); Takaaki NODA, Toyama-shi (JP); Yuki TAIRA, Toyama-shi (JP); Lingchuan YAO, Toyama-shi (JP)

(73) Assignee: Kokusai Electric Corporation, Tokyo (JP)

(21) Appl. No.: 19/644,056

(22) Filed: Apr. 10, 2026

(30) Foreign Application Priority Data
Apr. 18, 2025 (JP) 2025-069017

(51) Int. Cl. C23C 16/455; C23C 16/04; C23C 16/509; H01J 37/32; H10P 14/60; H10P 14/692

(52) U.S. Cl. CPC C23C 16/45534; C23C 16/045; C23C 16/45542; C23C 16/5093; H01J 37/3244; H10P 14/6339; H01J 2237/332; H10P 14/6926

(57) ABSTRACT

There is provided a technique that forms a film containing a predetermined element in a recess by performing, a predetermined number of times, a cycle including (a) forming an adsorption inhibition layer that inhibits adsorption of a second processing agent in the recess by supplying a first processing agent to a substrate having the recess, (b) forming a first layer containing the predetermined element and a first halogen element in the recess by supplying the second processing agent containing the predetermined element and the first halogen element to the substrate after (a) is started, (c) modifying the first layer to a second layer by supplying a third processing agent that reacts with the first layer to the substrate, and (d) desorbing at least a part of the first halogen element from a surface of the second layer by supplying a plasma excited fourth processing agent to the substrate.

### CROSS-REFERENCE TO RELATED APPLICATION

This application is based upon and claims the benefit of priority from Japanese Patent Application No. 2025-069017, filed on Apr. 18, 2025, the entire contents of which are incorporated herein by reference.

### FIELD OF THE INVENTION

The present disclosure relates to a method of processing a substrate, a method of manufacturing a semiconductor device, a recording medium, and a substrate processing apparatus.

### DESCRIPTION OF THE RELATED ART

As a step out of steps of manufacturing a semiconductor device, processing of forming a film on a substrate may be performed.

### SUMMARY

The present disclosure provides a technique capable of controlling a film thickness distribution in a recess in processing of forming the film in the recess.

According to one aspect of the present disclosure, provided is a technique of forming a film containing a predetermined element in a recess by performing, a predetermined number of times, a cycle including:
(a) forming an adsorption inhibition layer that inhibits adsorption of a second processing agent in the recess by supplying a first processing agent to a substrate having the recess;
(b) forming a first layer containing the predetermined element and a first halogen element in the recess by supplying the second processing agent containing the predetermined element and the first halogen element to the substrate after (a) is started;
(c) modifying the first layer to a second layer by supplying a third processing agent that reacts with the first layer to the substrate; and
(d) desorbing at least a part of the first halogen element from a surface of the second layer by supplying a plasma excited fourth processing agent to the substrate.

### BRIEF DESCRIPTION OF THE DRAWINGS

FIG. 1 is a schematic configuration diagram of a vertical processing furnace of a substrate processing apparatus suitably used in one embodiment of the present disclosure, illustrating a longitudinal cross-sectional view of a processing furnace 202 portion.

FIG. 2 is a schematic configuration diagram of the vertical processing furnace of the substrate processing apparatus suitably used in one embodiment of the present disclosure, illustrating a cross-sectional view of the processing furnace 202 portion taken along line A-A of FIG. 1.

FIG. 3A is a perspective view when electrodes 300-1 and 300-2 suitably used in one embodiment of the present disclosure are installed in an electrode fixture 301. FIG. 3B is a diagram illustrating a positional relationship among a heater 207, the electrode fixture 301, the electrodes 300-1 and 300-2, a protrusion 310 for fixing the electrodes 300-1 and 300-2, and a reaction tube 203 suitably used in one embodiment of the present disclosure.

FIG. 4 is a schematic configuration diagram of a controller 121 of the substrate processing apparatus suitably used in one embodiment of the present disclosure, and is a block diagram illustrating a control system of the controller 121.

FIG. 5 is a diagram illustrating a processing sequence in one embodiment of the present disclosure.

FIG. 6A is an enlarged cross-sectional view of a wafer 200 after step A is performed. FIG. 6B is an enlarged cross-sectional view of the wafer 200 after step B is performed. FIG. 6C is an enlarged cross-sectional view of the wafer 200 after step C is performed. FIG. 6D is an enlarged cross-sectional view of the wafer 200 after step D is performed.

FIG. 7 is a diagram illustrating an example of a processing sequence in modified example 1 of the present disclosure.

FIG. 8 is a schematic configuration diagram of a vertical processing furnace of a substrate processing apparatus suitably used in modified example 4 of the present disclosure, illustrating a horizontal cross-sectional view of a processing furnace portion.

### DETAILED DESCRIPTION

### One Embodiment of Present Disclosure

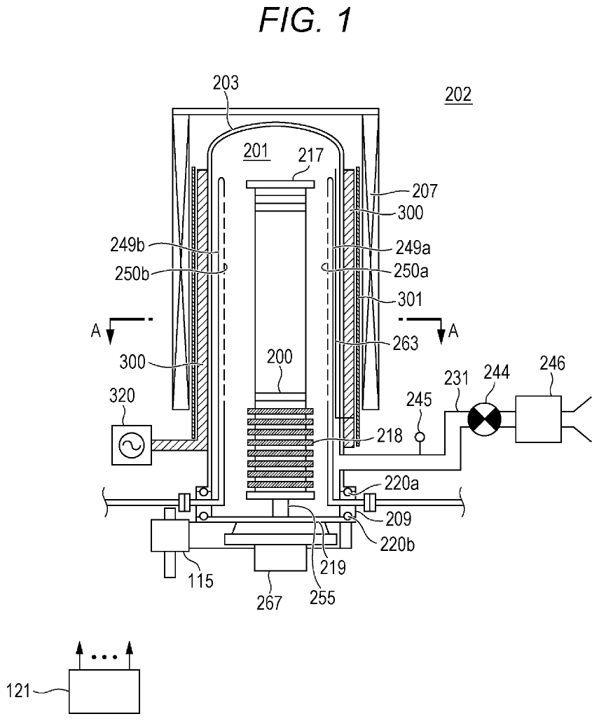

One embodiment of the present disclosure will be hereinafter described mainly with reference to FIGS. 1 to 5 and FIGS. 6A to 6D. Note that the drawings used in the following description are all schematic, and a dimensional relationship between elements, a ratio between elements and the like illustrated in the drawings do not necessarily coincide with actual ones. Between a plurality of drawings, the dimensional relationships between the elements, the ratios between the elements and the like do not necessarily coincide with each other.

### (1) Configuration of Substrate Processing Apparatus

As illustrated in FIG. 1, a processing furnace 202 includes a heater 207 serving as a temperature regulator (heater). The heater 207 also functions as an activator (heat exciter) that thermally activates (excites) a gas.

An electrode fixture 301 described later is disposed inside the heater 207, and an electrode 300 of a plasma generator described later is further disposed inside the electrode fixture 301. Furthermore, inside the electrode 300, a reaction tube 203 is disposed concentrically with the heater 207. The reaction tube 203 is composed of, for example, a heat-resistant material such as quartz (SiO₂) or silicon carbide (SiC), and is formed into a cylindrical shape with an upper end closed and a lower end opened. A manifold 209 is disposed below the reaction tube 203. An O-ring 220a serving as a seal member is provided between the manifold 209 and the reaction tube 203. A processing container (reaction container) is composed mainly of the reaction tube 203 and the manifold 209. A processing chamber 201 is formed in a cylinder hollow portion of the processing container. The processing chamber 201 is configured to be able to accommodate wafers 200 serving as a plurality of substrate. Note that the processing container is not limited to the configuration described above, and there is a case where only the reaction tube 203 is referred to as the processing container.

### (Gas Supplier)

In the processing chamber 201, nozzles 249a and 249b serving as first and second suppliers, respectively, are provided so as to penetrate through a side wall of the manifold 209. Gas supply pipes 232a and 232b are connected to the nozzles 249a and 249b, respectively. In this manner, in the processing container, the two nozzles 249a and 249b and the two gas supply pipes 232a and 232b are arranged such that a plurality of types of gases can be supplied into the processing chamber 201.

The gas supply pipes 232a and 232b are provided with mass flow controllers (MFCs) 241a and 241b serving as flow rate controllers (flow rate controllers) and valve 243a and 243b serving as on/off valves, respectively, in this order from an upstream side of a gas flow. Gas supply pipes 232c and 232e are connected to the gas supply pipe 232a on a downstream side of the valve 243a. Gas supply pipes 232d and 232f are connected to the gas supply pipe 232b on a downstream side of the valve 243b. In the gas supply pipes 232c to 232f, MFCs 241c to 241f and valves 243c to 243f are provided, respectively, in this order from the upstream side of the gas flow.

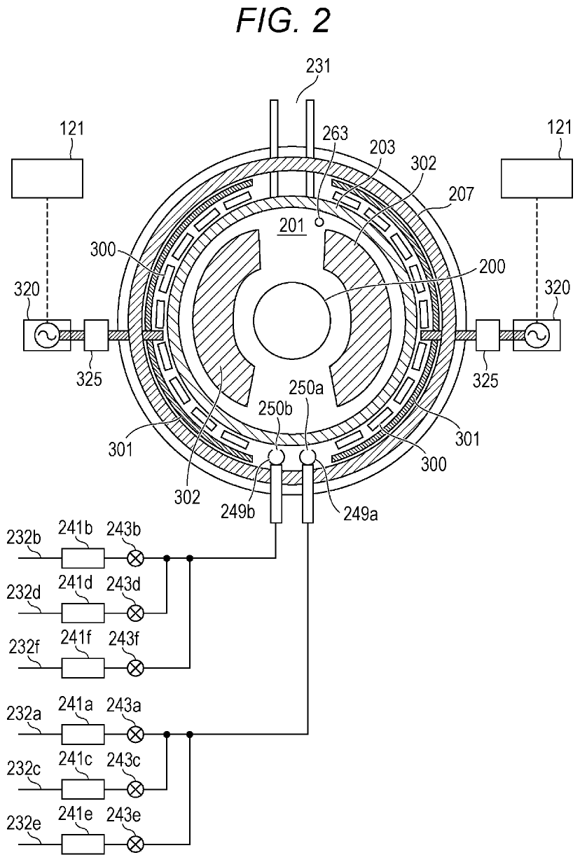

As illustrated in FIGS. 1 and 2, the nozzles 249a and 249b are provided in a space between an inner wall of the reaction tube 203 and the wafers 200 so as to extend upward in an arrangement direction of the wafers 200 along the inner wall of the reaction tube 203 from a lower portion toward an upper portion. On side surfaces of the nozzles 249a and 249b, gas supply holes 250a and 250b through which a gas is supplied are provided, respectively. The gas supply holes 250a and 250b are each opened so as to be opposed to (face) an exhaust port 231a in plan view, and can supply the gas toward the wafer 200. A plurality of gas supply holes 250a and a plurality of gas supply holes 250b are provided from the lower portion to the upper portion of the reaction tube 203.

A first processing agent is supplied from the gas supply pipe 232a into the processing chamber 201 via the MFC 241a, the valve 243a, and the nozzle 249a.

A third processing agent is supplied from the gas supply pipe 232b into the processing chamber 201 via the MFC 241b, the valve 243b, and the nozzle 249b.

A second processing agent is supplied from the gas supply pipe 232c into the processing chamber 201 via the MFC 241c, the valve 243c, the gas supply pipe 232a, and the nozzle 249a.

A fourth processing agent is supplied from the gas supply pipe 232d into the processing chamber 201 via the MFC 241d, the valve 243d, the gas supply pipe 232b, and the nozzle 249b.

From the gas supply pipes 232e and 232f, an inert gas is supplied into the processing chamber 201 via the MFCs 241e and 241f, the valves 243e and 243f, the gas supply pipes 232a and 232c, and the nozzles 249a and 249b, respectively. The inert gas acts as a purge gas, a carrier gas, a diluent gas and the like.

A first processing agent supply system is composed mainly of the gas supply pipe 232a, the MFC 241a, and the valve 243a. A third processing agent supply system is composed mainly of the gas supply pipe 232b, the MFC 241b, and the valve 243b. A second processing agent supply system is composed mainly of the gas supply pipe 232c, the MFC 241c, and the valve 243c. A fourth processing agent supply system is composed mainly of the gas supply pipe 232d, the MFC 241d, and the valve 243d. An inert gas supply system is composed mainly of the gas supply pipes 232e and 232f, the MFCs 241e and 241f, and the valves 243e and 243f. The first to fourth processing agent supply systems are collectively referred to as a processing agent supply system. The nozzle connected to the gas supply pipe forming each of the above-described various supply systems may be included in the supply system.

### (Substrate Support)

As illustrated in FIG. 1, a boat 217 serving as a substrate support is configured to support a plurality of, for example, 25 to 200 wafers 200 in multiple stages, that is, to arrange the wafers 200 at intervals, while the wafers 200 are aligned in the vertical direction in a horizontal posture and in a state in which the centers thereof are aligned with one another. Heat insulating plates 218 each composed of a heat-resistant material such as quartz or SiC, for example, are supported in multiple stages in a lower portion of the boat 217.

### (Plasma Generator)

Next, a plasma generator will be described with reference to FIG. 1 to FIGS. 3A and 3B.

The electrode 300 for plasma generation is provided outside the reaction tube 203, that is, outside (outer periphery of) the processing container (processing chamber 201). By applying power to the electrode 300, it is possible to turn a gas into plasma and excite the plasma inside the reaction tube 203, that is, inside the processing container (processing chamber 201), that is, it is possible to excite the gas into a plasma state. Hereinafter, exciting the gas into the plasma state is also simply referred to as plasma excitation. The electrode 300 is configured to generate capacitively coupled plasma (CCP) in the reaction tube 203, that is, in the processing container (processing chamber 201) by applying high-frequency power (RF power).

Specifically, as illustrated in FIG. 2, the electrode 300 and the electrode fixture 301 for fixing the electrode 300 are arranged between the heater 207 and the reaction tube 203. The electrode fixture 301 is disposed inside the heater 207, the electrode 300 is disposed inside the electrode fixture 301, and the reaction tube 203 is disposed inside the electrode 300.

As illustrated in FIGS. 1 and 2, the electrode 300 and the electrode fixture 301 are provided in an annular space in a plan view between an inner wall of the heater 207 and an outer wall of the reaction tube 203 so as to extend upward in an arrangement direction of the wafers 200 along the outer wall of the reaction tube 203 from a lower portion toward an upper portion. The electrode 300 is provided in parallel with the nozzles 249a and 249b. The electrode 300 and the electrode fixture 301 are arrayed to be arranged concentrically with the reaction tube 203 and the heater 207 and in non-contact with the heater 207 in plan view.

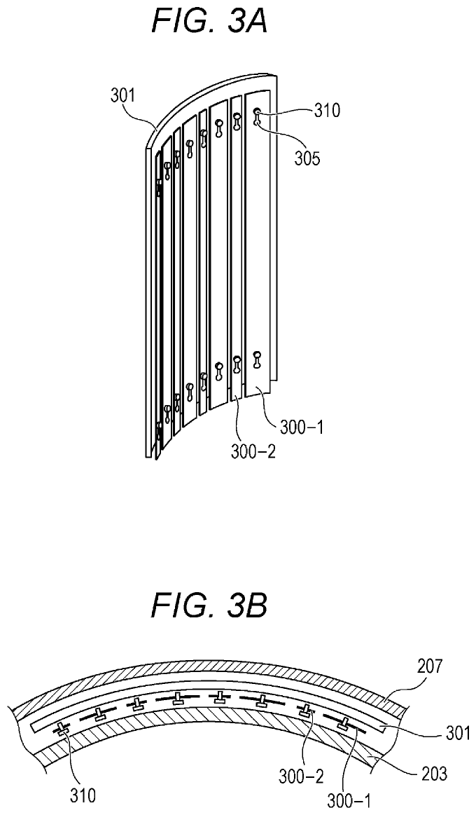

As illustrated in FIG. 2, a plurality of electrodes 300 is provided, and the plurality of electrodes 300 is fixed and installed on the inner wall of the electrode fixture 301. More specifically, a protrusion 310 capable of hooking the electrode 300 is provided on the inner wall surface of the electrode fixture 301, and the electrode 300 is provided with an opening 305, which is a through-hole through which the protrusion 310 can be inserted. Note that FIG. 2 illustrates an example in which nine electrodes 300 are fixed to one electrode fixture 301, and the configuration (unit) includes two sets. FIGS. 3A and 3B illustrate an example of the configuration (unit) in which eight electrodes 300-1 and 300-2 are fixed to one electrode fixture 301.

As illustrated in FIGS. 2 and 3A, the electrode 300 includes a first electrode 300-1 and a second electrode 300-2. The first electrode 300-1 is connected to a high-frequency power supply (RF power supply) 320 through a matcher 325, and any potential is applied to the first electrode 300-1. The second electrode 300-2 is grounded and has a reference potential (0 V). The first electrode 300-1 is also referred to as a Hot electrode, and the second electrode 300-2 is also referred to as a Ground electrode. Each of the first electrode 300-1 and the second electrode 300-2 is configured as a plate-shaped member having a rectangular shape in a front view. FIGS. 2, 3A, and 3B illustrate an example in which four first electrodes 300-1 and four second electrodes 300-2 are provided. By applying RF power between the first electrode 300-1 and the second electrode 300-2 from the RF power supply 320 through the matcher 325, plasma is generated in a region between the first electrode 300-1 and the second electrode 300-2. This region is also referred to as a plasma generation region. As illustrated in FIG. 2, the electrodes 300 (first electrode 300-1 and second electrode 300-2) are arranged in such a manner that a longitudinal direction extends in a stacking direction in which the plurality of wafers 200 is stacked, and are arranged on an arc in plan view. The electrode 300 is disposed between the reaction tube 203 and the heater 207 while being fixed to the inner wall surface of the electrode fixture 301 disposed in a substantially arc shape in plan view along the outer wall of the reaction tube 203.

For example, a high frequency not lower than 25 MHz and not higher than 35 MHz is input to the electrode 300 from the RF power supply 320 via the matcher 325, so that plasma 302 is generated inside the reaction tube 203. According to the plasma 302 generated in this manner, an active species for substrate processing can be supplied to the surface of the wafer 200 from around the wafer 200.

A plasma generator (plasma exciter) that excites (activates) a gas to a plasma state is mainly composed of the electrode 300. The electrode fixture 301, the matcher 325, and the RF power supply 320 may be included in the plasma generator.

### (Exhauster)

In the reaction tube 203, an exhaust pipe 231 that discharges an atmosphere in the processing chamber 201 is disposed as illustrated in FIG. 1. To the exhaust pipe 231, a vacuum pump 246 serving as a vacuum exhauster is connected via a pressure sensor 245 serving as a pressure detector (pressure detector) that detects a pressure in the processing chamber 201 and an auto pressure controller (APC) valve 244 serving as an exhaust valve (pressure regulator). The APC valve 244 is configured to be able to perform vacuum exhaust and stop the vacuum exhaust inside the processing chamber 201 by opening and closing the valve in a state in which the vacuum pump 246 is operated, and to be able to regulate a pressure in the processing chamber 201 by regulating a degree of valve opening on the basis of pressure information detected by the pressure sensor 245 in a state in which the vacuum pump 246 is operated. An exhaust system is composed mainly of the exhaust pipe 231, the APC valve 244, and the pressure sensor 245. The vacuum pump 246 may be included in the exhaust system.

### (Peripheral Device)

Below the manifold 209, a seal cap 219 serving as a furnace lid capable of airtightly closing a lower end opening of the manifold 209 is disposed. The seal cap 219 is configured to abut a lower end of the manifold 209 from below in the vertical direction. An O-ring 220b serving as a seal member that abuts the lower end of the manifold 209 is provided on an upper surface of the seal cap 219.

On a side of the seal cap 219 opposite to the processing chamber 201, a rotator 267 that rotates a boat 217 is arranged. A rotating shaft 255 of the rotator 267 penetrates the seal cap 219 and is connected to the boat 217. The rotator 267 is configured to rotate the boat 217, thereby rotating the wafer 200. The seal cap 219 is configured to be lifted up and down in a vertical direction by a boat elevator 115 serving as a lifter arranged vertically outside the reaction tube 203. The boat elevator 115 is configured to be able to load/unload the boat 217 into/from the processing chamber 201 by lifting the seal cap 219 up and down.

The boat elevator 115 is configured as a transferrer (transferrer) that transfers the boat 217, that is the wafer 200 into/from the processing chamber 201.

A temperature sensor 263 serving as a temperature detector is provided in the reaction tube 203. By regulating the degree of energization to the heater 207 on the basis of temperature information detected by the temperature sensor 263, the temperature in the processing chamber 201 has a desired temperature distribution.

### (Controller)

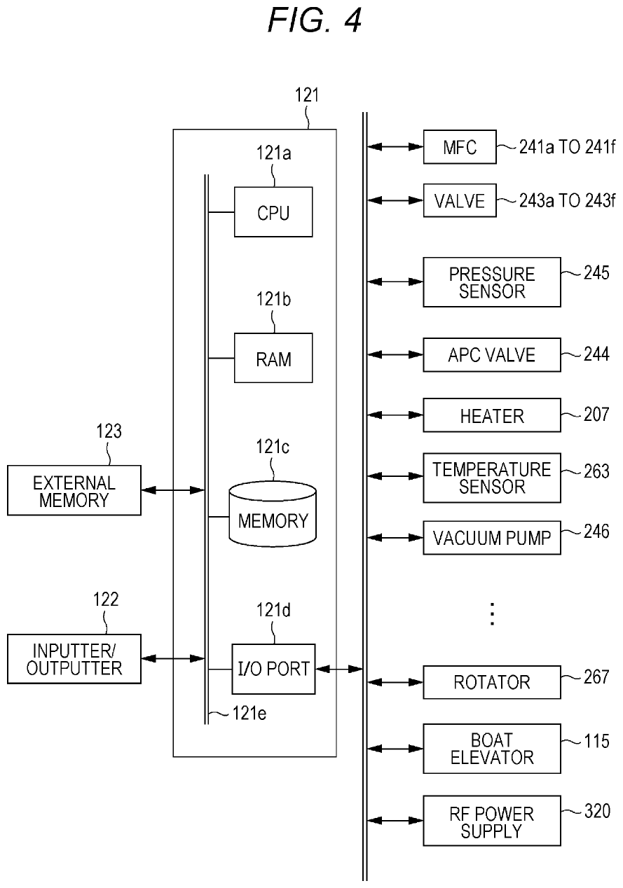

Next, a controller will be described with reference to FIG. 4. As illustrated in FIG. 4, a controller 121 that is a controller (controller) is configured as a computer including a central processing unit (CPU) 121a, a random access memory (RAM) 121b, a memory 121c, and an I/O port 121d. The RAM 121b, the memory 121c, and the I/O port 121d are configured to be able to exchange data with the CPU 121a via an internal bus 121e. An inputter/outputter 122 configured as, for example, a touch panel and the like is connected to the controller 121.

The memory 121c includes, for example, a flash memory, a hard disk drive (HDD), a solid state drive (SSD) and the like. In the memory 121c, a control program that controls an operation of the substrate processing apparatus, a process recipe in which procedures, conditions and the like of substrate processing to be described later are described and the like are readably recorded and stored. The process recipe is a combination formed such that the controller 121 causes the substrate processing apparatus to execute each procedure in substrate processing to be described later to obtain a predetermined result, and functions as a program. Hereinafter, the process recipe, the control program and the like are collectively and simply referred to as a program (program product). The process recipe is simply referred to as a recipe. In a case where the term program is used in the present specification, this might include the recipe alone, the control program alone, or both of them. The RAM 121b is configured as a memory area in which programs, data and the like read by the CPU 121a are temporarily stored.

The I/O port 121d is connected to the MFCs 241a to 241f, the valves 243a to 243f, the pressure sensor 245, the APC valve 244, the vacuum pump 246, the heater 207, the temperature sensor 263, the rotator 267, the boat elevator 115, the RF power supply 320 and the like described above.

The CPU 121a is configured to read the control program from the memory 121c and execute the control program, and read the recipe from the memory 121c in response to an input and the like of an operation command from the inputter/outputter 122. The CPU 121a is configured to be able to control, in accordance with a content of the read recipe, a flow rate regulating operation of various gases by the MFCs 241a to 241f, an opening/closing operation of the valves 243a to 243f, an opening/closing operation of the APC valve 244, and a pressure regulating operation by the APC valve 244 based on the pressure sensor 245, start and stop of the vacuum pump 246, a temperature regulating operation of the heater 207 based on the temperature sensor 263, a rotation and rotating speed regulating operation of the boat 217 by the rotator 267, a lifting operation of the boat 217 by the boat elevator 115, power supply of the RF power supply 320 and the like.

The controller 121 can be configured by installing the above-described program recorded and stored in the external memory 123 into the computer. Examples of the external memory 123 include a magnetic disk such as an HDD, an optical disk such as a CD, and a semiconductor memory such as a USB memory or an SSD, for example. The memory 121c and the external memory 123 are configured as computer-readable recording media. Hereinafter, they are collectively and simply referred to as recording media. In a case where the term recording medium is used in the present specification, this might include a case where only the memory 121c alone is included, a case where only the external memory 123 alone is included, or a case where both of them are included. Note that the program may be provided to the computer by using a communicator such as the Internet and a dedicated line without using the external memory 123.

### (2) Substrate Processing Step

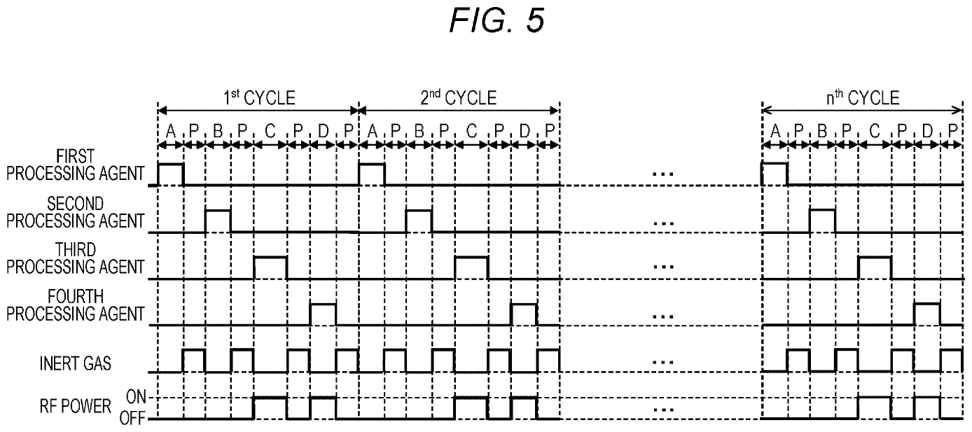

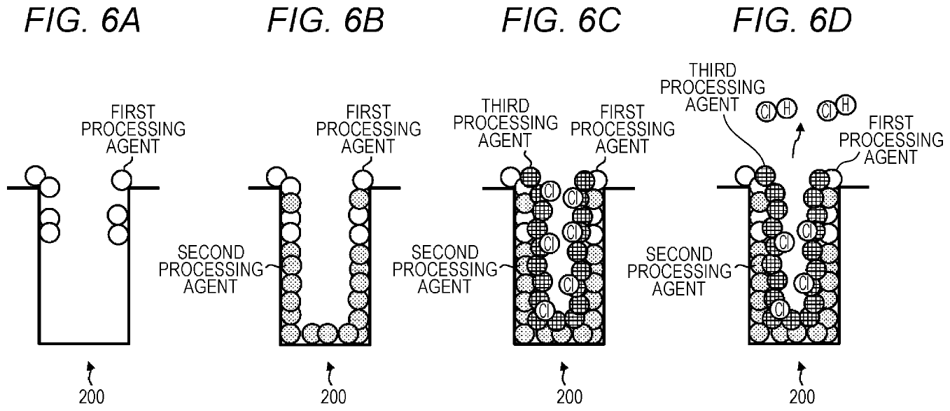

As a step of steps of manufacturing a semiconductor device using the substrate processing apparatus described above, an example of a method of processing a substrate, that is, a processing sequence for forming a film on a surface of the wafer 200 as the substrate will be described mainly with reference to FIGS. 5 and 6A to 6D. In the following description, the controller 121 controls the operation of each unit forming the substrate processing apparatus.

In the present embodiment, an example of using the wafer 200 in which a recess such as a trench, a groove, or a hole having a three-dimensional structure is formed on the surface thereof will be described. In the present specification, the term “recess” is not limited to a shape having a bottom surface, and may include, for example, a structure such as a gap (gap) or a through hole without a bottom surface. In a case of the structure without a bottom surface, the “bottom side” may mean a direction (side) from each opening toward the back side of the structure as seen from each of two or more openings.

In the processing sequence in the present embodiment, a cycle including:
(a) step A of forming an adsorption inhibition layer that inhibits adsorption of the second processing agent on a surface in the recess by supplying the first processing agent to the wafer 200 having the recess;
(b) step B of forming a first layer containing a predetermined element and a first halogen element on the surface in the recess by supplying the second processing agent containing the predetermined element and the first halogen element to the wafer 200 after step A is started;
(c) step C of modifying the first layer to the second layer by supplying the third processing agent that reacts with the first layer to the wafer 200; and
(d) step D of desorbing at least a part of the first halogen element from a surface of the second layer by supplying a plasma excited fourth processing agent to the wafer 200, is performed a predetermined number of times (n times, n is 1 or an integer of 2 or larger) to form a film containing the predetermined element in the recess.

In the following example, as illustrated in FIG. 5, a case where the first processing agent and the second processing agent are not plasma excited at steps A and B (that is, a case where steps A and B are performed in a non-plasma atmosphere) will be described, and a case where the third processing agent and the fourth processing agent are plasma excited at steps C and D will be described.

In the following example, a case where the first processing agent contains a predetermined element and the second halogen element, and the predetermined element contained in the first processing agent and the predetermined element contained in the second processing agent are the same element will be described.

In the present specification, the above-described processing sequence may be expressed as described later for convenience. A similar expression will be used in the following description of other embodiments, modified examples and the like.

(First processing agent→purge→second processing agent→purge→plasma excited third processing agent→plasma excited fourth processing agent→purge)×n

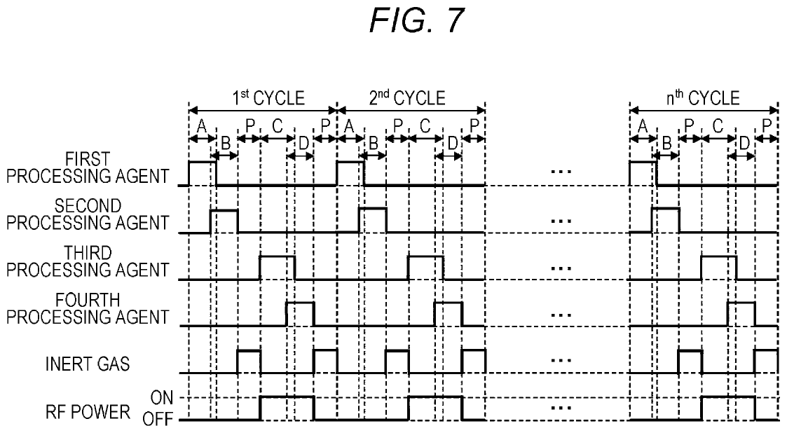

In FIG. 5, execution periods of steps A, B, C, and D are represented as A, B, C, and D, respectively. A purge execution period is represented by P. The same applies to FIG. 7.

The term “wafer” used in the present specification might mean the wafer itself, or a laminate of the wafer and a predetermined layer or film formed on a surface thereof. The term “surface of the wafer” used in the present specification might mean the surface of the wafer itself or a surface of a predetermined layer and the like formed on the wafer. The expression “forming a predetermined layer on the surface of the wafer” in the present specification might mean that a predetermined layer is directly formed on the surface of the wafer itself or that a predetermined layer is formed on the layer and the like formed on the wafer. In a case where the term “substrate” is used in the present specification, this is a synonym of the term “wafer”.

The term “agent” and “substance” used in the present specification include at least either a gaseous substance or a liquid substance. The liquid substance includes a mist substance. That is, each of the first to fourth processing agents may contain the gaseous substance, the liquid substance such as the mist substance, or both thereof.

The term “layer” used in the present specification includes at least either a continuous layer or a discontinuous layer. For example, the adsorption inhibition layer and first and second layers may contain the continuous layer, the discontinuous layer, or both of them.

In the present specification, the adsorption and reaction of the first to fourth processing agents to the surface of the wafer may include not only an embodiment in which they are adsorbed to and reacted with the surface of the wafer in an undecomposed state, but also an embodiment in which they are decomposed and an intermediate produced by desorption of a ligand is adsorbed to and reacted with the surface of the wafer.

### (Wafer Charge and Boat Load)

When a plurality of wafers 200 is loaded on the boat 217, the lower end opening of the manifold 209 is opened. Thereafter, as illustrated in FIG. 1, the boat 217 that supports the plurality of wafers 200 is raised by the boat elevator 115 and is loaded into the processing chamber 201. In this manner, the wafer 200 is prepared in the processing chamber 201.

### (Pressure Regulation and Temperature Regulation)

After the boat load is finished, the inside of the processing chamber 201 is vacuum-exhausted (decompression-exhausted) by the vacuum pump 246 so as to achieve a desired pressure (vacuum degree). The heater 207 heats in such a manner that temperature of the wafer 200 in the processing chamber 201 reaches desired processing temperature. The rotator 267 starts to rotate the wafer 200. Both the exhaust in the processing chamber 201, the heating and rotation of the wafer 200 continue at least until the processing on the wafer 200 is finished.

### (Film Forming Processing)

Thereafter, steps A to D are sequentially executed.

### [Step A]

At step A, the first processing agent containing the predetermined element and the second halogen element is supplied to the wafer 200 in the processing chamber 201. Specifically, the valve 243a is opened to allow the first processing agent to flow into the gas supply pipe 232a. The first processing agent a flow rate of which is regulated by the MFC 241a is supplied into the processing chamber 201 via the nozzle 249a, and discharged from the exhaust port 231a. At that time, the first processing agent is supplied to the wafer 200 (first processing agent supply). At that time, the valves 243e and 243f may be opened to supply the inert gases into the processing chamber 201 through the nozzles 249a and 249b, respectively.

Processing conditions when supplying the first processing agent at this step are exemplified as follows:
processing temperature: 300 to 700 °C, preferably 400 to 650 °C,
processing pressure: 100 to 4,000 Pa, preferably 100 to 1,000 Pa,
first processing agent supply flow rate: 0.1 to 3 slm,
first processing agent supply time: 1 to 100 seconds, preferably 1 to 30 seconds, and
inert gas supply flow rate (each gas supply pipe): 0 to 10 slm.

In the present specification, an expression of a numerical range such as “300 to 700 °C” means that a lower limit value and an upper limit value are included in the range. Therefore, for example, “300 to 700 °C” means “equal to or higher than 300 °C and equal to lower than 700 °C”. The same applies to other numerical ranges. In the present specification, the processing temperature means the temperature of the wafer 200 or the temperature in the processing chamber 201, and the processing pressure means the pressure in the processing chamber 201, in other words, the pressure in a space in which the wafer 200 is present (processed). The processing time means a time in which the processing is continued. In a case where 0 slm is included in the supply flow rate, 0 slm means a case where the substance (gas) is not supplied. The same applies to the following description.

By supplying the first processing agent to the wafer 200 under the above-described processing conditions, at least either the first processing agent or a partial structure of the molecule thereof (hereinafter, also referred to as the first processing agent and the like) can be adsorbed to a first adsorption site present on a surface of a first region (specifically, a region on an opening side of the recess), which is a part of the recess (refer to FIG. 6A). By allowing the first processing agent and the like to adsorb to the first adsorption site present on the surface of the first region, it is possible to form a layer (hereinafter, also referred to as a layer A) terminated (hereinafter, also referred to as a second halogen-terminated) by an atom of the second halogen element in a state of containing a predetermined element and being bonded to an atom of the predetermined element in the region. Specifically, under the above-described processing conditions, a part of the bond between the predetermined element and the second halogen element in the first processing agent is broken, and an atom of the predetermined element having a dangling bond is adsorbed to the first adsorption site present on the surface of the first region, whereby the layer A can be formed.

In the layer A, adsorption of at least either the second processing agent supplied at step B described later or the partial structure of the molecule thereof (hereinafter, also referred to as the second processing agent and the like) is suppressed (inhibited) by the second halogen termination formed on the surface. In other words, the layer A forms the adsorption inhibition layer that inhibits adsorption of the second processing agent and the like onto the layer A. In other words, the layer A forms an adsorption inhibition layer that inhibits adsorption of the second processing agent and the like to the first adsorption site to which the first processing agent or the like is adsorbed, the first adsorption site present on the surface of the first region.

In the present embodiment, as preprocessing of this step, it is preferable to perform, for example, a preflow for supplying the third processing agent to be used at step C described later to the wafer 200. In the preflow, for example, by supplying a nitriding agent containing nitrogen (N) and hydrogen (H) as the third processing agent, an NH termination as the first adsorption site can be formed on the surface of the wafer 200. As a result, at this step and step B described later, the first processing agent and the second processing agent can be easily adsorbed. A procedure of the preflow can be, for example, similar to that in which step C described later is performed under a non-plasma atmosphere.

As the first processing agent, a substance containing the predetermined element and the second halogen element can be used. In a case where the predetermined element is Si, halosilane can be used as the first processing agent. As the second halogen element, at least one element of chlorine (Cl), fluorine (F), bromine (Br), and iodine (I) can be used.

As the first processing agent, for example, a gas containing chlorosilane such as tetrachlorosilane (SiCl₄), monochlorosilane (SiH₃Cl), dichlorosilane (SiH₂Cl₂), trichlorosilane (SiHCl₃), hexachlorodisilane (Si₂Cl₆), octachlorotrisilane (Si₃Cl₈), monochlorodisilane (Si₂H₅Cl), dichlorodisilane (Si₂H₄Cl₂), trichlorodisilane (Si₂H₃Cl₃), tetrachlorodisilane (Si₂H₂Cl₄), monochlorotrisilane (Si₃H₅Cl), or dichlorotrisilane (Si₃H₄Cl₂) can be used.

As the first processing agent, in addition to chlorosilane, it is also possible to use, for example, fluorosilane such as tetrafluorosilane (SiF₄) or difluorosilane (SiH₂F₂), bromosilane such as tetrabromosilane (SiBr₄) or dibromosilane (SiH₂Br₂), or iodosilane such as tetraiodosilane (SiI₄) or diiodosilane (SiH₂I₂).

As the first processing agent, for example, it is preferable to use a gas containing a compound (for example, SiCl₄, SiF₄, SiBr₄, SiI₄) having a molecular structure in which atoms of the second halogen element are bonded to all bonding hands of atoms (Si) of a predetermined element among halosilanes described above.

One or more of them can be used as the first processing agent.

As the inert gas, for example, a rare gas such as a nitrogen (N₂) gas, an argon (Ar) gas, a helium (He) gas, a neon (Ne) gas, or a xenon (Xe) gas can be used. One or more of them can be used as the inert gas. The same applies to each step to be described later.

After the adsorption inhibition layer is formed on the surface in the recess of the wafer 200, the valve 243a is closed to stop supplying the first processing agent into the processing chamber 201. Then, the inside of the processing chamber 201 is vacuum-exhausted to remove the gaseous substance and the like remaining in the processing chamber 201 from the inside of the processing chamber 201. At that time, the valves 243e and 243f are opened to supply the inert gases into the processing chamber 201 through the nozzles 249a and 249b, respectively. The inert gas supplied from the nozzles 249a and 249b acts as a purge gas, and accordingly, the inside of the processing chamber 201 is purged.

### [Step B]

After step A is finished, a raw material as the second processing agent containing the predetermined element and the first halogen element is supplied to the wafer 200 in the processing chamber 201, that is, the wafer 200 after the adsorption inhibition layer is formed on the inner surface in the recess.

Specifically, the valve 243c is opened to allow the second processing agent to flow into the gas supply pipe 232c. The second processing agent a flow rate of which is regulated by the MFC 241c is supplied into the processing chamber 201 via the nozzle 249a, and discharged from the exhaust port 231 a. At that time, the second processing agent is supplied to the wafer 200 (second processing agent supply). At that time, the valves 243e and 243f may be opened to supply the inert gases into the processing chamber 201 through the nozzles 249a and 249b, respectively.

Processing conditions when supplying the second processing agent at this step are exemplified as follows:
second processing agent supply flow rate: 0.1 to 3 slm; and
second processing agent supply time: 1 to 100 seconds, preferably 1 to 30 seconds. Other processing conditions can be similar to the processing conditions when supplying the first processing agent at step A.

By supplying the second processing agent to the wafer 200 under the above-described processing conditions, the second processing agent and the like can be adsorbed to the first adsorption site present on the surface of the second region (specifically, a region on a bottom side of the recess), which is another part in the recess (refer to FIG. 6B). By allowing the second processing agent and the like to adsorb to the first adsorption site present on the surface of the second region, the first layer containing the predetermined element and the first halogen element can be formed in the region. Specifically, under the above-described processing conditions, at least either a bond between the predetermined elements (for example, a Si—Si bond) in the second processing agent or a bond between the predetermined element and the first halogen element (for example, a Si—Cl bond) is broken, and an atom of the predetermined element having a dangling bond can be adsorbed to the first adsorption site present in the second region, whereby the first layer containing the predetermined element and the first halogen element can be formed.

At least a part of the first region where the adsorption inhibition layer is formed and at least a part of the second region where the first layer is formed may overlap each other on the surface in the recess. In other words, the first layer may be formed on at least a part of the first adsorption site remaining in a gap between the adsorption inhibition layers formed discontinuously (refer to FIG. 6B).

As the second processing agent, a substance containing the predetermined element and the first halogen element can be used. As the second processing agent, for example, halosilane containing Si serving as the predetermined element as a main element forming the film formed on the wafer 200 can be used. As the first halogen element, at least one element of Cl, F, Br, and I can be used. The second halogen element of the second processing agent and the first halogen element of the first processing agent may be the same element or different elements from each other.

As the second processing agent, one or more substances (halosilanes) listed as the first processing agent can be used. Note that the first processing agent and the second processing agent are substances having different molecular structures.

As the second processing agent, for example, it is preferable to use a compound (for example, Si₂Cl₆, Si₃Cl₈, Si₂H₅Cl, Si₂H₄Cl₂) having a molecular structure in which atoms (Si) of the predetermined element are bonded among halosilanes described above.

As the first processing agent, it is preferable to use a compound (for example, SiCl₄) having a molecular structure in which atoms of the second halogen element are bonded to all bonding hands of atoms (Si) of a predetermined element, and as the second processing agent, it is preferable to use a compound (for example, Si₂Cl₆) having a molecular structure in which atoms (Si) of the predetermined element are bonded. In this case, the ratio of the number of atoms of the second halogen element to the number of atoms of the predetermined element contained in the adsorption inhibition layer (for example, 4/1) is larger than the ratio of the number of atoms of the first halogen element to the number of atoms of the predetermined element contained in the first layer (for example, 6/2).

After the first layer is formed on the surface in the recess of the wafer 200, the valve 243c is closed to stop supplying the second processing agent into the processing chamber 201. Then, the gas substance and the like remaining in the processing chamber 201 are removed from the inside of the processing chamber 201 by processing procedures similar to the purge at step A.

### [Step C]

After step B is finished, a reactant as the third processing agent is plasma excited and supplied to the wafer 200 in the processing chamber 201, that is, the wafer 200 after the first layer is formed on the inner surface in the recess.

Specifically, the valve 243b is opened to allow the third processing agent to flow into the gas supply pipe 232b. The third processing agent a flow rate of which is regulated by the MFC 241b is supplied into the processing chamber 201 via the nozzle 249b (third processing agent supply). At that time, high-frequency power is supplied (applied) from the RF power supply 320 to the electrode 300. The third processing agent supplied into the processing chamber 201 is plasma excited inside the processing chamber 201 to generate an active species (excited species). At that time, the third processing agent containing the active species is supplied to the wafer 200. At that time, the valves 243e and 243f may be opened to supply the inert gases into the processing chamber 201 through the nozzles 249a and 249b, respectively.

Processing conditions when supplying the third processing agent at this step are exemplified as follows:
processing pressure: 2 to 100 Pa, preferably 20 to 70 Pa;
third processing agent supply flow rate: 0.1 to 10 slm,
third processing agent supply time: 10 to 600 seconds, preferably 10 to 60 seconds,
RF power: 100 to 1,000 W, and
RF frequency: 25 to 35 MHz. Other processing conditions can be similar to the processing conditions when supplying the first processing agent at step A.

By supplying the third processing agent to the wafer 200 under the above-described processing conditions, the first layer and the layer A (that is, the adsorption inhibition layer) formed on the surface in the recess react with the third processing agent, and are modified to the second layer. As a result, the second layer is formed on the surface in the recess. (Refer to FIG. 6C)

That is, the second layer is composed of a layer obtained by modifying the first layer by reacting with the third processing agent, and a layer obtained by modifying the layer A (adsorption inhibition layer) by reacting with the third processing agent. In the present specification, the layer obtained by modifying the first layer by reacting with the third processing agent may be particularly referred to as a second layer.

For example, by supplying a nitriding agent described later as the third processing agent, the first halogen element and the second halogen element contained in the first layer and the layer A are desorbed, and the NH termination as the first adsorption site can be formed on the surface of the second layer. Note that, at that time, some of the first halogen element and the second halogen element contained in the first layer and the layer A cannot be desorbed and remain on the surface of the second layer (refer to FIG. 6C, FIG. 6C illustrates an example in which Cl remains as the first halogen element). In the second layer, while the adsorption of the first processing agent supplied at step A in a next cycle can be promoted by the first adsorption site formed on the surface thereof, the adsorption of the first processing agent is inhibited by at least either the first halogen element or the second halogen element remaining on a part of the surface thereof.

As the third processing agent, for example, a nitriding agent can be used. As the nitriding agent, for example, a gas containing an N and H-containing substance can be used. As the N and H-containing substance, a hydrogen nitride-based substance such as ammonia (NH₃), diazene (N₂H₂), hydrazine (N₂H₄), or N₃H₈ can be used, for example.

In addition to them, for example, a gas containing an N, carbon (C), and hydrogen (H)-containing substance can also be used as the third processing agent. As the N, C, and H-containing substance, for example, an amine-based substance such as an ethylamine-based substance such as monoethylamine (C₂H₅NH₂), diethylamine ((C₂H₅)₂NH), or triethylamine ((C₂H₅)₃N), and a methylamine-based substance such as monomethylamine (CH₃NH₂), dimethylamine ((CH₃)₂NH), or trimethylamine ((CH₃)₃N), an organic hydrazine-based substance such as monomethylhydrazine ((CH₃)HN₂H₂), dimethylhydrazine ((CH₃)₂N₂H₂), or trimethylhydrazine ((CH₃)₂N₂(CH₃)H) and the like can be used.

One or more of them can be used as the third processing agent. For example, in a case where the nitriding agent is used as the third processing agent, a radical containing N (for example, N*) or an ion containing N can be used as the active species generated by plasma excitation. For example, in a case where the N and H-containing substance is used as the third processing agent, a radical containing N and H (for example, NH*) or an ion containing NH can be used as the active species generated by plasma excitation. Note that * means a radical. The same applies to the following description.

After the second layer is formed on the surface in the recess of the wafer 200, the valve 243b is closed to stop supplying the third processing agent into the processing chamber 201. Then, the gas substance and the like remaining in the processing chamber 201 are removed from the inside of the processing chamber 201 by processing procedures similar to the purge at step A.

### [Step D]

After step C is finished, the fourth processing agent is plasma excited and supplied to the wafer 200 in the processing chamber 201, that is, the wafer 200 after the second layer is formed on the inner surface in the recess.

Specifically, the valve 243d is opened to allow the fourth processing agent to flow into the gas supply pipe 232d. The fourth processing agent a flow rate of which is regulated by the MFC 241d is supplied into the processing chamber 201 via the nozzle 249b (fourth processing agent supply). At that time, high-frequency power is supplied (applied) from the RF power supply 320 to the electrode 300. The fourth processing agent supplied into the processing chamber 201 is plasma excited inside the processing chamber 201 to generate an active species. At that time, the fourth processing agent containing the active species is supplied to the wafer 200. At that time, the valves 243e and 243f may be opened to supply the inert gases into the processing chamber 201 through the nozzles 249a and 249b, respectively.

Processing conditions when supplying the fourth processing agent at this step are exemplified as follows:
processing pressure: 2 to 100 Pa, preferably 20 to 70 Pa;
fourth processing agent supply flow rate: 0.1 to 10 slm,
fourth processing agent supply time: 5 to 450 seconds, preferably 0.5 to 30 seconds,
RF power: 100 to 1,000 W, and
RF frequency: 25 to 35 MHz. Other processing conditions can be similar to the processing conditions when supplying the third processing agent at step C.

By supplying the fourth processing agent to the wafer 200 under the above-described processing conditions, at least a part of the first halogen element and the second halogen element can be desorbed from the surface of the second layer (refer to FIG. 6D). Hereinafter, at least either the first halogen element and the second halogen element may be collectively and simply referred to as a “halogen element”.

By desorbing at least a part of the first halogen element and the second halogen element from the surface of the second layer, the first adsorption site formed at the portion (place) where the first halogen element or the second halogen element is desorbed can function as the adsorption site of the first processing agent and the like. It may be said that, by desorbing at least a part of the first halogen element and the second halogen element from the surface of the second layer, the first adsorption site to which the first processing agent and the like can adsorb may be formed or increased.

By supplying the fourth processing agent to the wafer 200 under the above-described processing conditions, at least a part of the first halogen element and the second halogen element can be desorbed from the surface of the second layer so that the density of the first halogen element and the second halogen element on the opening side of the recess becomes smaller than the density of the first halogen element and the second halogen element on the bottom side of the recess (including the density at which at least either the first halogen element or the second halogen element is present). In other words, at least either the first halogen element or the second halogen element remaining on the opening side of the recess can be selectively (preferentially) removed more than at least either the first halogen element or the second halogen element remaining on the bottom side of the recess (refer to FIG. 6D). At that time, the distribution of the densities of the first halogen element and the second halogen element in the recess can be regulated by regulating at least any of the magnitude of the RF power, the processing pressure, or the fourth processing agent supply time out of the above-described processing conditions. For example, as the supply time of the fourth processing agent is shortened, the first halogen element on the opening side of the recess can be locally removed.

As the fourth processing agent, for example, a gas containing a H-containing substance can be used. For example, as the H-containing substance, a substance containing only a single H element such as H₂ can be used.

As the fourth processing agent, a gas containing a deuterium (D)-containing substance may be supplied in place of or in addition to the H-containing substance. For example, as the D-containing substance, a substance containing only a single D element such as D₂ can be used.

For example, in a case where the H-containing substance is used as the fourth processing agent, a radical containing H (for example, H*) or an ion containing H can be used as the active species generated by plasma excitation. As the fourth processing agent, it is preferable to use a substance in which the life of the active species generated by plasma excitation is shorter than the life of the active species contained in the plasma excited third processing agent. Examples of the combination of active species having such a life relationship include a radical containing N and H (for example, NH*) generated by plasma exciting the N and H-containing substance that is the third processing agent, and a radical containing H and containing no N (for example, H*) generated by plasma exciting the H-containing substance that is the fourth processing agent and has a shorter life. In this manner, by supplying the fourth processing agent containing the active species (for example, H*) having a relatively short life, the active species is deactivated on the opening side before reaching the bottom side of the recess, so that at least either the first halogen element and the second halogen element on the opening side of the recess can be locally removed.

After at least a part of the first halogen element and the second halogen element is desorbed from the surface of the second layer, the valve 243d is closed to stop the supply of the fourth processing agent into the processing chamber 201. Then, the gas substance and the like remaining in the processing chamber 201 are removed from the inside of the processing chamber 201 by processing procedures similar to the purge at step A.

### [Perform Predetermined Number of Times]

By performing a cycle of non-simultaneously (alternately or intermittently) performing steps A, B, C, and D described above in this order n times (n is an integer of 1 or 2 or larger), a film containing a predetermined element can be formed in the recess of the wafer 200. The film formed in the recess of the wafer 200 can form an inner space of the recess that communicates with an outer space of the recess. For example, in a case of using the second processing agent containing Si and the third processing agent containing N described above, for example, a silicon nitride film (SiN film) can be formed in the recess. In a case of using the third processing agent containing N and C, for example, a silicon carbonitride film (SiCN film) can be formed in the recess. The above-described cycle is preferably repeated twice or more until a thickness of the film formed by stacking the second layer becomes a desired film thickness.

### (After-Purge and Atmospheric Pressure Restoration)

After the film forming processing is finished, the inert gas serving as the purge gas is supplied from each of the nozzles 249a and 249b into the processing chamber 201 and is discharged from the exhaust port 231a. As a result, the interior of the processing chamber 201 is purged, and the gas remaining in the processing chamber 201 and reaction by-products and the like are removed from the interior of the processing chamber 201. Thereafter, the atmosphere inside the processing chamber 201 is replaced with the inert gas, and the pressure inside the processing chamber 201 is returned to a normal pressure.

### (Boat Unload and Wafer Discharge)

Thereafter, the boat elevator 115 lowers the seal cap 219, and the lower end of the manifold 209 is opened. Then, the processed wafer 200 is unloaded from the lower end of the manifold 209 to the outside of the reaction tube 203 in a state of being supported by the boat 217. After being unloaded to the outside of the reaction tube 203, the processed wafer 200 is taken out from the boat 217.

### (3) Effects by Present Embodiment

According to the present embodiment, one or a plurality of effects described below can be obtained.
(a) At step A, the film thickness distribution in the recess can be controlled by supplying the first processing agent to the wafer 200 having the recess. Specifically, at step A, when the first processing agent is supplied to form the adsorption inhibition layer that inhibits adsorption of the second processing agent, it is regulated so that the first processing agent is adsorbed to the opening side (near the opening) of the recess. As a result, at step B, the second processing agent can be easily adsorbed to the bottom side as compared with the opening side of the recess. As a result, for example, step coverage of the formed film can be improved.

At step D, by supplying the plasma excited fourth processing agent and desorbing at least a part of the first halogen element and the second halogen element (that inhibit adsorption of the first processing agent) from the surface of the second layer, the first processing agent can be adsorbed to the surface in the recess at step A in the next cycle.

At step D, the plasma excited fourth processing agent is supplied. The plasma excited fourth processing agent has a shorter life than the fourth processing agent that is not plasma excited. In this manner, by supplying the active species having a relatively short life generated by plasma exciting the fourth processing agent, the arrival probability of the fourth processing agent to the bottom side of the recess is reduced, and the fourth processing agent can mainly reach the opening side of the recess. This makes it possible to preferentially desorb at least either the first halogen element and the second halogen element remaining on the opening side of the recess. As a result, at step A in the next cycle, the first processing agent can be effectively adsorbed to the opening side of the recess.
(b) By performing the cycle including steps A to D twice or more, the adsorption of the first processing agent particularly in the second and subsequent cycles is promoted, and controllability of the film thickness distribution in the recess can be improved. Specifically, for example, the step coverage of the film can be improved.
(c) The first processing agent contains the second halogen element, so that a second halogen-terminated adsorption inhibition layer can be formed at step A. The second halogen termination formed on the surface of the adsorption inhibition layer can inhibit the adsorption of the second processing agent and the like at step B and improve the controllability of the film thickness distribution in the recess. Specifically, for example, the step coverage of the film can be improved.
(d) The first processing agent contains the predetermined element, so that, at step A, adsorptivity (easiness of adsorption) to the surface in the recess can be enhanced. By forming the adsorption inhibition layer containing the predetermined element, at step C, the adsorption inhibition layer (layer A) is modified together with the first layer and can form the second layer, so that a deposition rate (deposition rate) of the film can be improved.
(e) The ratio of the number of atoms of the second halogen element to the number of atoms of the predetermined element contained in the adsorption inhibition layer is larger than the ratio of the number of atoms of the first halogen element to the number of atoms of the predetermined element contained in the first layer, so that an adsorption inhibition effect of the second processing agent and the like by the first processing agent can be enhanced.

Thus, the locality of the adsorption inhibition effect on the opening side of the recess at step D can be further enhanced. Hereinafter, this will be described.

As described above, the adsorption inhibition effect of the second processing agent and the like by the second halogen termination formed on the surface of the adsorption inhibition layer at step A is higher than the adsorption inhibition effect of the second processing agent and the like by the first halogen element remaining in the second layer at step C. Therefore, when performing step D to desorb the first halogen element remaining in the second layer (formed on the opening side of the recess) and thereafter forming the adsorption inhibition layer in a portion from which the first halogen element has been desorbed at step A in the next cycle, the adsorption inhibition effect in the portion can be relatively enhanced as compared with a case where step A is performed without performing step D.
(f) The first processing agent contains a compound having a molecular structure in which atoms of the second halogen element are bonded to all the bonding hands of atoms of the predetermined element, so that the adsorption inhibition effect of the second processing agent and the like by the second halogen element can be enhanced when the first processing agent is adsorbed to the surface in the recess.
(g) The second processing agent contains a compound having a molecular structure including a bond between atoms (for example, Si) of a predetermined element, so that the Si-Si bond is easily thermally decomposed by being broken by thermal energy. As a result, a highly reactive dangling bond of Si is adsorbed to the surface in the recess, and the adsorption rate (deposition rate) can be increased.
(h) At step D, at least either the first halogen element or the second halogen element can be desorbed from the surface of the second layer so that the density of the first halogen element and the second halogen element on the opening side of the recess is smaller than the density of the first halogen element and the second halogen element on the bottom side of the recess. As a result, it is possible to allow the first processing agent and the like to preferentially adsorb to the opening side of the recess at step A in the next cycle to form the adsorption inhibition layer, so that the adsorption suppression effect of the second processing agent and the like on the opening side can be enhanced, and the step coverage of the film can be improved.
(i) The third processing agent contains N and H, so that the first layer can be nitrided and at least a part of the first halogen element contained in the first layer can be removed.
(j) The fourth processing agent contains at least either H₂ or D₂ (that is, a substance containing only a single H element or only a single D element), the first halogen element remaining on the surface of the second layer can be efficiently removed. By using a substance containing at least either H₂ or D₂ having a relatively shorter life of the active species as the fourth processing agent, the active species (for example, H*) is deactivated on the opening side before reaching the bottom side of the recess, so that at least either the first halogen element or the second halogen element on the opening side of the recess can be locally removed.
(k) At step A, the first processing agent and the like are adsorbed to the first adsorption site present on the surface of the first region that is a part of the recess. At step B, the second processing agent and the like are adsorbed to the first adsorption site present on the surface of the second region that is another part in the recess. In this manner, by regulating the region to which the first processing agent is adsorbed, the region to which the second processing agent is adsorbed can be controlled. As a result, the thickness distribution of the film to be formed can be regulated.
(l) By desorbing at least a part of the first halogen element and the second halogen element from the surface of the second layer, the first adsorption site to which the first processing agent and the like can adsorb may be formed or increased on the surface in the recess. As a result, the adsorption site (first adsorption site) of the first processing agent supplied at step A in the next cycle can be formed in a desired region, so that the film thickness distribution can be easily controlled. Specifically, for example, the step coverage of the film can be improved.
(m) At step D, it is possible to regulate the distribution of the densities of the first halogen element and the second halogen element in the recess by regulating at least any of the magnitude of the RF power, the processing pressure, or the fourth processing agent supply time that are the processing conditions when supplying the fourth processing agent. In this manner, by regulating a removal range of the first halogen element in the recess, the adsorption distribution of the first processing agent at step A in the next cycle can be controlled. As a result, the film thickness distribution in the recess can be regulated, and the step coverage can be particularly improved.
(n) At step C, the desorption of the first halogen element contained in the first layer can be promoted by supplying the third processing agent to the wafer 200 in a plasma excited state. As a result, the adsorption of the first processing agent supplied at step A in the next cycle can be further promoted, and the adsorption suppression effect of the second processing agent and the like can be enhanced.
(o) Step C and step D are performed non-simultaneously, and step D is performed after step C. As a result, step C can be performed in a state in which an entire surface in the recess of the first layer is terminated (hereinafter, also simply referred to as halogen-terminated) by at least one atom of the first halogen element or the second halogen element, so that the surface in the recess can be uniformly modified. In contrast, when step C is performed in a state in which the halogen termination on the opening side of the recess is locally removed at step D, nitridation due to a reaction between, for example, NH₃ as the third processing agent and, for example, Cl as an atom of a halogen element is suppressed on the opening side of the recess, and a deviation in nitriding amount (density) may occur in the recess.

### (4) Modified Examples

(i) The processing sequence according to the present embodiment can be modified as in the following modified examples. These modified examples can be optionally combined. Unless otherwise specifically described, processing procedures and processing conditions at each step of each of the modified examples can be made similar to the processing procedures and processing conditions at each step of the processing sequence described above.

### Modified Example 1

Step D may include an execution period that is started after a lapse of predetermined time from the start of step C and overlaps with an execution period of step C (refer to FIG. 7).

In the present modified example also, effects similar to those in the above-described embodiment can be obtained. In the present modified example, the required time per cycle can be further shortened, and the throughput can be improved. Note that, in this modified example, at step C, nitridation by a reaction between, for example, NH₃ as the third processing agent and, for example, Cl as an atom of the first halogen element may be insufficient. Therefore, from the viewpoint of uniformity of the nitriding amount (density) in the recess, the above-described embodiment may be more preferable.

Step B may include an execution period that is started after a lapse of predetermined time from the start of step A and overlaps with an execution period of step A (refer to FIG. 7).

In the present modified example also, effects similar to those in the above-described embodiment can be obtained. In the present modified example, the required time per cycle can be further shortened, and the throughput can be improved.

### Modified Example 2

The processing pressure at step D may be higher than the processing pressure at step C.

In the present modified example also, effects similar to those in the above-described embodiment can be obtained. In the present modified example, by further shortening the mean free path of the active species contained in the plasma excited fourth processing agent, at least either the first halogen element or the second halogen element remaining on the opening side of the recess can be locally removed.

### Modified Example 3

The magnitude of the RF power at step D may be smaller than the magnitude of the RF power at step C.

In the present modified example also, effects similar to those in the above-described embodiment can be obtained. In the present modified example, by further reducing the excited power and shortening the life of the active species contained in the fourth processing agent and/or reducing the active species concentration, at least either the first halogen element or the second halogen element remaining on the opening side of the recess can be locally removed.

(ii) The processing apparatus according to the present embodiment can be modified as in the following modified examples. Unless otherwise specifically described, the configuration in each modified example is similar to the configuration in the above-described embodiment, and elements substantially the same as the elements described in FIG. 1 are denoted by the same reference numerals, and the description thereof will be omitted.

### Modified Example 4

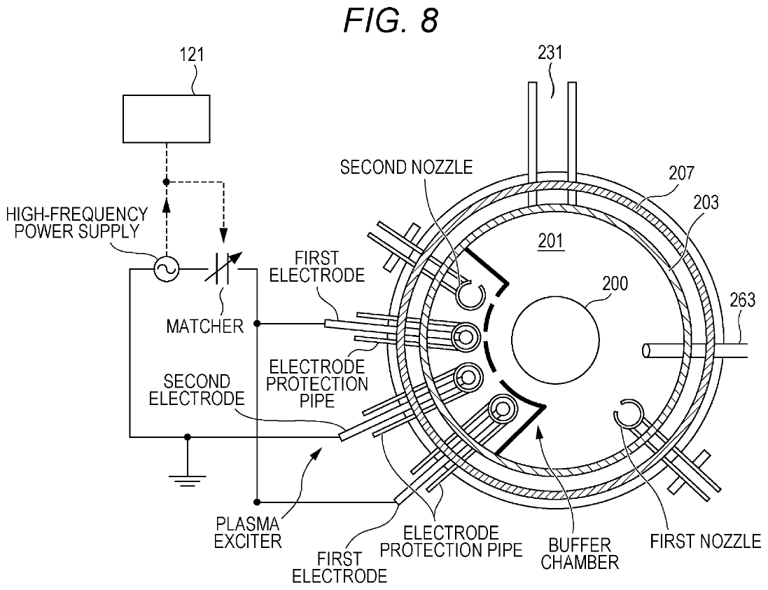

As illustrated in FIG. 8, the processing chamber may further include a buffer chamber, the second nozzle may be configured to supply a gas into the processing chamber through the buffer chamber, and the first nozzle may be configured to supply a substance (gas) into the processing chamber without intervention of through the buffer chamber. Furthermore, a plasma exciter including first and second electrodes and an electrode protection tube that plasma excites the gas supplied into the buffer chamber may be provided inside the buffer chamber.

Specifically, as illustrated in FIG. 8, in the buffer chamber, two rod-shaped first electrodes composed of a conductor and one rod-shaped second electrode are arranged in a stacking direction (arrangement direction) of the wafers 200 from the lower portion to the upper portion of the reaction tube 203. Each of the first and second electrodes is provided in parallel with the second nozzle. Each of the first and second electrodes is protected by being covered with the electrode protection tube. Two first electrodes arranged at both ends of the first and second electrodes are connected to a high-frequency power supply via a matcher, and the second electrode is connected to the ground that is a reference potential and is grounded. The grounded second electrode is disposed so as to be sandwiched between two adjacent first electrodes connected to the high-frequency power supply, and is configured such that one first electrode and the second electrode and the other first electrode and the second electrode form a pair to generate plasma.

In the present modified example also, effects similar to those in the above-described embodiment can be obtained.

### Other Embodiments of Present Disclosure

The embodiments of the present disclosure have been specifically described above. However, the present disclosure is not limited to the above-described embodiments, and can be variously modified without departing from the gist thereof.

For example, a substance not containing the predetermined element and containing the second halogen element, that is, a gas containing a halogen-containing substance can be used as the first processing agent. As the halogen-containing substance, it is possible to use, for example, F₂, Cl₂, Br₂, I₂, nitrogen trifluoride (NF₃), chlorine trifluoride (ClF₃), a hydrogen fluoride (HF) gas, a hydrogen chloride (HCl) gas, a hydrogen bromide (HBr) gas, hydrogen iodine (HI) and the like. Also in the present embodiment, effects similar to those in the above-described embodiments can be obtained.

As the first processing agent, for example, a substance containing Si and an amino group, that is, a gas containing aminosilane can also be used. The amino group is a monovalent functional group obtained by removing hydrogen (H) from ammonia, a primary amine, or a secondary amine, and can be represented as —NH₂, —NHR, or —NR₂. Note that R represents an alkyl group, and two Rs in —NR₂ may be the same or different. As the aminosilane, for example, tetrakis(dimethylamino)silane (Si[N(CH₃)₂]₄), tris(dimethylamino)silane (Si[N(CH₃)₂]₃H), a bis(diethylamino)silane (Si[N(C₂H₅)₂]₂H₂), a bis(tertiary butylamino)silane (SiH₂[NH(C₄H₉)]₂), or (diisopropylamino)silane (SiH₃[N(C₃H₇)₂]) can also be used. One or more of them can be used as the first processing agent. Also in the present embodiment, effects similar to those in the above-described embodiments can be obtained.

For example, the predetermined element contained in the first and second processing agents may be a metallic element such as titanium (Ti), zirconium (Zr), hafnium (Hf), tantalum (Ta), niobium (Nb), aluminum (Al), molybdenum (Mo), tungsten (W), or germanium (Ge). For example, in a case where the first and second processing agents containing these metal elements as the predetermined elements and the third processing agent as the nitriding agent are used, metal-based nitride films such as a titanium nitride film (TiN film), a zirconium nitride film (ZrN film), a hafnium nitride film (HfN film), a tantalum nitride film (TaN film), a niobium nitride film (NbN film), an aluminum nitride film (AlN film), a molybdenum nitride film (MoN film), a tungsten nitride film (WN film), and a germanium nitride film (GeN film) can be formed. In a case where a substance containing N and C is used as the third processing agent, a metal-based carbonitride film containing these metal elements can be formed. Also in the present embodiment, effects similar to those in the above-described embodiments can be obtained.

For example, an oxygen (O)-containing substance such as oxygen (O₂), ozone (O₃), O₂+H₂, water vapor (H₂°), hydrogen peroxide (H₂O₂), nitrous oxide (N₂O), nitrogen monoxide (NO), nitrogen dioxide (NO₂), carbon monoxide (CO), or carbon dioxide (CO₂) may be used as the third processing agent, and an O-containing film such as a silicon oxide film (SiO film) may be formed on the surface of the wafer 200 by the above-described processing agent sequence. Joint representation of two substances such as “O₂+H₂” in the present specification means a mixed substance of H₂ and O₂. In a case of supplying the mixed substance, two substances may be mixed (premixed) in a supply pipe and then supplied into the processing chamber 201, or the two substances may be separately supplied into the processing chamber 201 from different supply pipes and mixed (post-mixed) in the processing chamber 201. One or more of them can be used as the third processing agent. In the present embodiment also, at least a part of effects of the above-described embodiments can be obtained.

For example, as the third processing agent, a substance containing only a single N element such as N₂ and a mixed substance such N₂+H₂ can be used. Since the life of the active species (for example, N*) generated by plasma excitation of N₂ is shorter than the life of the active species (for example, H*) generated by plasma excitation of H₂, in a case where H₂ is used as the fourth processing agent, it is preferable not to use N₂ as the third processing agent from the viewpoint of locally removing the first halogen element on the opening side of the recess. In the present embodiment also, at least a part of effects of the above-described embodiments can be obtained.

For example, between step C of supplying the nitriding agent as the third processing agent to the wafer 200 and step D, a step of supplying the above-described O-containing substance to the wafer 200 may be performed, and the O-containing film such as the silicon oxynitride film (SiON film) may be formed on the surface of the wafer 200. In the present embodiment also, at least a part of effects of the above-described embodiments can be obtained.

At step C, the third processing agent may be supplied to the wafer 200 without plasma excitation (that is, under a non-plasma atmosphere). In the present embodiment, the processing temperature is preferably 600 to 750 °C. In the present embodiment, a hydrogen nitride-based substance is preferably used as the third processing agent. In the present embodiment also, at least a part of effects of the above-described embodiments can be obtained.

For example, as the fourth processing agent, a rare gas such as N₂, Ar, He, Ne, or Xe can be used. In the present embodiment also, at least a part of effects of the above-described embodiments can be obtained. Since the life of N* generated by plasma exciting an N₂ gas is shorter than the life of H*, in a case where N₂ is used as the fourth processing agent, the first halogen element on the opening side of the recess can be more locally removed at step D.

For example, as a plasma generation method, inductively coupled plasma may be used in addition to CCP. Also in this case, effects similar to those in the above-described embodiment can be obtained.

Preferably, a recipe used in each processing is individually prepared according to processing contents and is recorded and stored in the memory 121c via an electric communication line or the external memory 123. When each processing is started, the CPU 121a preferably appropriately selects an appropriate recipe from among the plurality of recipes recorded and stored in the memory 121c according to the processing contents. As a result, it is possible to form films with various film types, composition ratios, film qualities, and film thicknesses with excellent reproducibility with one processing apparatus. It is possible to reduce a burden on an operator, and it is possible to start each piece of processing quickly while avoiding an operation error.

The above-described recipe is not limited to a newly created recipe and thus may be prepared, for example, by a change in an existing recipe already installed on the processing apparatus. In a case where the recipe is changed, the changed recipe may be installed on the processing apparatus through a telecommunication line or a recording medium on which the recipe is recorded. The existing recipe already installed on the processing apparatus may be directly changed by operating the inputter/outputter 122 included in the existing processing apparatus.

In the above-described various embodiments and various modified examples, an example of forming a film using a batch type processing apparatus that processes a plurality of substrates at a time has been described. The present disclosure is not limited to the above-described various embodiments and various modified examples, and can be appropriately applied to, for example, a case of forming a film using a single wafer type processing apparatus that processes one or a plurality of substrates at a time. In the above-described various embodiments and various modified examples, an example of forming a film using a processing apparatus including a hot wall type processing furnace has been described. The present disclosure is not limited to the above-described various embodiments and various modified examples, and can also be appropriately applied to a case of forming a film using a processing apparatus having a cold wall type processing furnace.

Even in a case where these processing apparatuses are used, it is possible to perform each processing under the processing procedures and processing conditions similar to the processing procedures and processing conditions in the above-described various embodiments and various modified examples. Therefore, it is possible to obtain the effects similar to those in the above-described various embodiments and various modified examples.

The above-described various embodiments and various modified examples can be appropriately combined and used. For example, the processing procedures and processing conditions at that time can be made similar to the processing procedures and processing conditions in the above-described various embodiments and various modified examples.

According to the present disclosure, it becomes possible to control a film thickness distribution in a recess in processing of forming the film in the recess.

What is claimed is

1. A method of processing a substrate comprising:
forming a film containing a predetermined element in a recess by performing, a predetermined number of times, a cycle including:
(a) forming an adsorption inhibition layer that inhibits adsorption of a second processing agent in the recess by supplying a first processing agent to the substrate having the recess;
(b) forming a first layer containing the predetermined element and a first halogen element in the recess by supplying the second processing agent containing the predetermined element and the first halogen element to the substrate after (a) is started;
(c) modifying the first layer to a second layer by supplying a third processing agent that reacts with the first layer to the substrate; and
(d) desorbing at least a part of the first halogen element from a surface of the second layer by supplying a plasma-excited fourth processing agent to the substrate.

2. The method according to claim 1, wherein the cycle is performed at least twice.

3. The method according to claim 1, wherein:
the first processing agent contains a second halogen element, and
in (a), the adsorption inhibition layer terminated by an atom of the second halogen element is formed in the recess.

4. The method according to claim 1, wherein:
the first processing agent contains the predetermined element and a second halogen element, and
in (a), the adsorption inhibition layer containing the predetermined element and terminated by an atom of the second halogen element in a state of being bonded to an atom of the predetermined element is formed in the recess.

5. The method according to claim 4, wherein a ratio of the number of atoms of the second halogen element to the number of atoms of the predetermined element contained in the adsorption inhibition layer is larger than a ratio of the number of atoms of the first halogen element to the number of atoms of the predetermined element contained in the first layer.

6. The method according to claim 4, wherein the first processing agent contains a compound having a molecular structure in which atoms of the second halogen element are bonded to all bonding hands of atoms of the predetermined element.

7. The method according to claim 1, wherein the second processing agent contains a compound having a molecular structure including a bond between atoms of the predetermined element.

8. The method according to claim 1, wherein in (d), the first halogen element is desorbed from the surface of the second layer so that a density of the first halogen element on an opening side of the recess is smaller than a density of the first halogen element on a bottom side of the recess.

9. The method according to claim 1, wherein the third processing agent contains nitrogen and hydrogen.

10. The method according to claim 1, wherein the fourth processing agent contains at least either H₂ or D₂.

11. The method according to claim 1, wherein:
in (a), at least either the first processing agent or a partial structure of a molecule of the first processing agent is adsorbed to a first adsorption site present on a surface of a first region that is a part of the recess, and
in (b), at least either the second processing agent or a partial structure of a molecule of the second processing agent is adsorbed to the first adsorption site present on a surface of a second region that is another part in the recess.

12. The method according to claim 1, wherein in (d), at least a part of the first halogen element is desorbed from the surface of the second layer to form a first adsorption site on the surface of the second layer, the first adsorption site to which at least either the first processing agent or a partial structure of a molecule of the first processing agent is able to be adsorbed.

13. The method according to claim 1, wherein in (d), a distribution of a density of the first halogen element in the recess is regulated by regulating at least any of magnitude of high-frequency power applied for plasma exciting the fourth processing agent, a pressure in a space in which the substrate is processed, or a supply time of the fourth processing agent.

14. The method according to claim 1, wherein in (c), the third processing agent is supplied to the substrate in a plasma-excited state.

15. The method according to claim 14, wherein a life of an active species contained in the plasma excited fourth processing agent is shorter than a life of an active species contained in the plasma excited third processing agent.

16. The method according to claim 1, wherein (c) and (d) are executed non-simultaneously, and (d) is executed after (c).

17. The method according to claim 1, wherein (d) is started after a lapse of a predetermined time from a start of (c) and includes an execution period that overlaps with an execution period of (c).

18. A method of manufacturing a semiconductor device, comprising the method according to claim 1.

19. A non-transitory computer-readable recording medium storing a program that causes, by a computer, a substrate processing apparatus to execute:
forming a film containing a predetermined element in a recess by performing, a predetermined number of times, a cycle including:
(a) forming an adsorption inhibition layer that inhibits adsorption of a second processing agent in the recess by supplying a first processing agent to a substrate having the recess;
(b) forming a first layer containing the predetermined element and a first halogen element in the recess by supplying the second processing agent containing the predetermined element and the first halogen element to the substrate after (a) is started;
(c) modifying the first layer to a second layer by supplying a third processing agent that reacts with the first layer to the substrate; and
(d) desorbing at least a part of the first halogen element from a surface of the second layer by supplying a plasma-excited fourth processing agent to the substrate.

20. A substrate processing apparatus comprising:
a processing agent supply system that supplies a first processing agent, a second processing agent, a third processing agent, and a fourth processing agent to a substrate having a recess;
a plasma exciter that plasma excites the fourth processing agent; and
a controller configured to be capable of controlling the processing agent supply system and the plasma exciter to perform forming a film containing a predetermined element in the recess by performing, a predetermined number of times, a cycle including:
(a) forming an adsorption inhibition layer that inhibits adsorption of a second processing agent in the recess by supplying a first processing agent to a substrate having the recess;
(b) forming a first layer containing the predetermined element and a first halogen element in the recess by supplying the second processing agent containing the predetermined element and the first halogen element to the substrate after (a) is started;
(c) modifying the first layer to a second layer by supplying a third processing agent that reacts with the first layer to the substrate; and
(d) desorbing at least a part of the first halogen element from a surface of the second layer by supplying the plasma-excited fourth processing agent to the substrate.
